(19) United States
(12) Patent Application Publication
(10) Pub. No.: US 2014/0191263 A1
(43) Pub. Date: Jul. 10, 2014

(54) COMPOSITIONS FOR AN LED REFLECTOR AND ARTICLES THEREOF

(71) Applicant: SABIC Innovative Plastics IP B.V., Bergen op Zoom (NL)

(72) Inventors: Liang Wang, Shanghai (CN); Takumi Shigeta, Tochigi (JP); Hongtao Shi, Shanghai (CN); Dake Shen, Shanghai (CN)

(21) Appl. No.: 13/851,534

(22) Filed: Mar. 27, 2013

Related U.S. Application Data
(60) Provisional application No. 61/849,810, filed on Jan. 7, 2013.

(51) Int. Cl. C08L 67/02; H01L 33/60

(52) U.S. Cl. CPC C08L 67/02; H01L 33/60
USPC 257/98; 362/341; 524/430; 524/413; 524/432; 524/423; 524/433; 524/91; 524/126; 524/302; 524/417

(57) ABSTRACT

Disclosed herein is a resin composition for molding a reflector for a light-emitting semiconductor diode comprising about 25 to about 80 wt. % of an heat-resistant aromatic polyester, about 5 to 50 wt. % of titanium dioxide filler; and about 5 to 50 wt. % of a glass fibers having a flat surface. In another aspect of the present invention, there is also provided a reflector for a light-emitting semiconductor element, which includes a molded product of the resin composition. In a further aspect of the present invention, there is also provided a light-emitting semiconductor unit comprising a light-emitting semiconductor diode element, leads connecting electrodes of the light-emitting semiconductor diode element with external electrodes, respectively, and the reflector.

### RELATED APPLICATION

This application claims priority to U.S. Provisional Application U.S. Ser. No. 61/849,810 (Docket P290228US2) filed on Jan. 7, 2013.

### BACKGROUND

This disclosure relates to a resin composition for a reflector and articles comprising the reflector. In particular, the invention relates to a resin composition for use in making a reflector for a light-emitting semiconductor unit. The invention also relates to a reflector having improved reflectance for a light-emitting semiconductor element, and further to a light-emitting semiconductor unit making use of the reflector.

A light-emitting diode (LED) is a semiconductor light source. LEDs are used as indicator lamps in many devices and are increasingly used for other lighting, including replacements for fluorescent lamps or incandescent light bulbs. An LED chip is usually mounted in an LED unit that provides two electrically isolated leads (cathode and anode) and a transparent encapsulant which serves as a lens.

An LED reflector is one of the important components for improving the luminance of an LED. Resin-made reflectors for use with light-emitting diodes have been widely known for many years. Such resin compositions typically comprise one or more fillers for providing the material with high reflectivity, which means that much light will be reflected back from the material at its surface interface. Such resin compositions should also have heat tolerance of at least 260° C. when used with surface-mount technology (SMT), which has replaced through-hole technology for making LED units.

Reflectors used in light-emitting diodes have been made from various thermoplastic resins such as PPA (polyphthalamide) combined with white pigments such as titanium oxide. For example, US Patent Publication 2010/0070072416, US Patent Publication 2011/015594, and US Patent Publication 2010/0053972 disclose various thermoplastic resins that have been used in making LED reflectors.

Still higher luminance and durability are desired for light-emitting diodes in the field of lighting. A great deal of effort has, therefore, been applied to the challenging problem of obtaining improvements in brightness per unit power consumption. In particular, there has been a strong demand from the market for higher durability coupled with improvements in photo-reflectance.

A challenge in obtaining improved resin compositions for a component of an LED unit is that the component is exposed to high temperatures during the manufacturing process. For example, an LED component can be exposed to heat when an epoxy sealing composition for the LED unit is cured. An LED component can also be exposed to temperatures of 260° C. and above during soldering operations. Furthermore, LED components can be routinely subjected to temperatures of 80° C. or more during use. Exposure to high temperatures can degrade or cause yellowing of resin compositions used to form LED components.

Furthermore, the use of resin compositions in reflectors for light-emitting diodes, especially ones that emit intense short-wavelength light, can cause the resin to become degraded or discolored by the light such that the reflectance is lowered over time. For example, since yellow surfaces can absorb blue light, surfaces that become yellowed by discoloration can lower the reflectance at a wavelength of 460 nm in particular.

Therefore, an object of the present invention is to provide a resin composition capable of affording a product that can retain whiteness, heat resistance, and mechanical properties, has a reflectivity of 90% or higher in a wavelength range of 300 to 750 nm, does not undergo deterioration of properties over time, and is effective for molding a reflector for a light-emitting semiconductor unit or a plurality of reflectors for such units. Another object of the present invention is to provide a reflector for a light-emitting semiconductor unit that makes use of the resin composition. A further object of the present invention is to provide a light-emitting semiconductor unit making use of the reflector.

### BRIEF SUMMARY OF THE INVENTION

Rod-shaped glass fibers have been commonly used in LED reflectors to increase the HDT (heat deflection temperature) of the material. Applicants unexpectedly found, however, that reflectors made from resin compositions using rod-shaped glass fiber can exhibit decreased initial reflectivity. Without wishing to be bound by theory, this decrease is believed to result from the glass fiber floating on the surface of the material during manufacture. Since initial reflectivity is an important customer consideration for an LED reflector, any such decrease is significantly undesirable.

Furthermore, LED reflectors made from resin compositions having a rod-shaped glass fiber were also unexpectedly found, over time, not to retain their reflectively as well as resin compositions comprising glass fibers having a flat surface.

Thus, Applicants have found that the reflectivity, and its retention, in an LED reflector can be improved by the use of glass fiber having a flat surface (“flat glass fiber”) to replace rod-shaped glass fiber in the materials used for making LED reflectors. In particular, applicants have unexpectedly found that initial reflectivity can be improved, and reflectivity after thermal-aging can be better retained, by the use of flat glass fiber in an LED reflector. Furthermore, such resin compositions exhibit other properties such as melt flow, heat deflection temperature (HDT), tensile modulus, and impact strength that are at least comparable to resin compositions using rod-shaped glass fibers, so the increase in LED reflectivity does not come at undue expense on balance.

One aspect of the present invention is directed to a resin composition for molding a reflector for a light-emitting semiconductor diode, the resin composition comprising:

about 25 to about 80 wt. % of a heat-resistant aromatic polyester having a melting point temperature of at least 260° C., of which
at least about 80 mole percent of the diol repeat units, derivable from 1,4-cyclohexanedimethanol, are of formula (I):

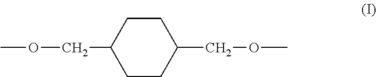

and at least about 80 mole percent of the dicarboxylic acid repeat units, derivable from terephthalic acid, are of formula (II):

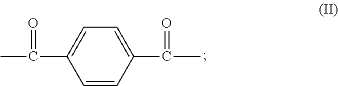

about 5 to 50 wt. % of titanium dioxide filler; and

about 5 to 50 wt. % of a glass fibers having a flat surface.

Another aspect of the present invention is directed to a resin composition for molding a reflector for a light-emitting semiconductor unit, the resin composition comprising:

about 30 to about 70 wt. % of an aromatic polyester of which
at least about 80 mole percent of the diol repeat units, derivable from 1,4-cyclohexanedimethanol, are of formula (I):

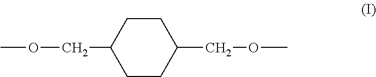

and at least about 80 mole percent of the dicarboxylic acid repeat units, derivable from terephthalic acid, are of formula (II):

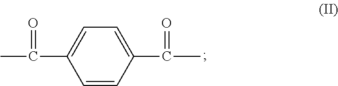

about 10 to 30 wt. % of titanium dioxide;

about 10 to 30 wt. % of a glass fibers having a flat surface and an aspect ratio in cross-section, of 1:1 to 5:1; and

0.1 to 10 wt. % of additives selected from the group consisting of light stabilizers, quenchers, antioxidant stabilizers, mold release agents, nucleating agents, and combinations thereof.

In another aspect of the present invention, there is provided a reflector for a light-emitting semiconductor unit, which includes a molded product of the above-described resin composition. The reflector can be integrally formed with a substrate supporting or under the light-emitting semiconductor unit, or the reflector can be separate from a substrate supporting or under the light-emitting semiconductor chip. The reflector can be in the form of a recessed body configured as a wall member surrounding the light-emitting semiconductor chip, in plain view, for reflecting light from the light-emitting semiconductor chip, optionally through a transparent sealant composition or lens.

A further aspect of the invention is directed to a light-emitting semiconductor package comprising a reflector and a solder, wherein the reflector comprises a resin composition comprising about 25 to about 80 wt. % of a heat-resistant aromatic polyester have a melting point temperature higher than the point of the solder; about 5 to 50 wt. % of titanium dioxide filler; and about 5 to 50 wt. % of glass fiber having a flat surface.

In a further aspect of the present invention, there is also provided a light-emitting semiconductor unit comprising a light-emitting semiconductor element, leads connected to the light-emitting semiconductor element, a wire or equivalent means connecting a lead to the light-emitting semiconductor chip, and the above-described reflector peripherally surrounding the light-emitting semiconductor chip, wherein the light-emitting semiconductor chip is optionally sealed within a transparent sealing composition. The transparent resin composition can optionally include a phosphor.

### BRIEF DESCRIPTION OF DRAWINGS

FIGS. 1A and 1B illustrate an embodiment of an LED unit having a reflector according to the present invention, in which FIG. 1A is a cross-sectional view of the LED unit taken along line X-X of FIG. 1B, and FIG. 1B is a plan view of the LED unit without showing the light-emitting semiconductor element and conductive wire;

FIG. 2 shows a graph comparing initial reflectance of a resin composition comprising flat glass fiber to a resin composition comprising commonly used rod-shaped glass fiber.

FIG. 3 shows a comparison of reflectance for materials having flat glass fiber and two common rod-shaped glass fibers, specifically a chart (A) showing initial reflectance and a chart (B) showing reflectance retention after simulated SMT (surface mount technology) processing at 260° C. for 5 minutes after pre-heat aging at 85° C. and 85% humidity for 168 hours.

### DETAILED DESCRIPTION OF THE INVENTION

Applicants have unexpectedly found that a composition comprising flat glass fiber in combination with an inorganic white filler such as titanium dioxide and a heat-resistant aromatic polyester such as poly 1,4-cyclohexanedimethylene terephthalate resin can significantly improve the properties of an LED reflector. In particular, surprisingly it was found that the use of the flat glass fiber can significantly improve reflectance and reflectivity, while at least maintaining desirable heat deflection temperature (HDT) and melt-flow. Other properties such as tensile stress and tensile elongation are at least comparable with those of using traditional rod-shaped glass fibers. Testing has shown that reflectors made with flat glass fiber can also pass the demands of SMT (surface-mount technology) processing at 260° C. or above.

In turn, a reflector made from a resin composition according to the present invention can be used in constructing a light-emitting semiconductor unit such as an LED unit. Such light-emitting semiconductor units have high photo-reflectance and undergo comparatively little or no reduction in luminance over time.

In one embodiment, an LED element (“chip”), a reflector, a lens, and other components are provided on one surface of a substrate. In another embodiment, a substrate portion (vertically below the LED element) and a reflector portion (vertically not below the LED element or its die pad) are continuously or integrally molded for use with an LED element, a lens, and other components. Such a reflector-substrate for LED mounting can form a continuous material.

As used herein the singular forms “a,” “an,” and “the” include plural referents. The term “combination” is inclusive of blends, mixtures, alloys, reaction products, and the like. Unless defined otherwise, technical and scientific terms used herein have the same meaning as is commonly understood by one of skill. Compounds are described using standard nomenclature. The term “and a combination thereof” is inclusive of the named component and/or other components not specifically named that have essentially the same function.

All ASTM tests and data are from the 2003 edition of the Annual Book of ASTM Standards unless otherwise indicated. All cited references are incorporated herein by reference.

For the sake of clarity, the terms terephthalic acid group, isophthalic acid group, butanediol group, ethylene glycol group in formulas have the following meanings. The term “terephthalic acid group” in a composition refers to a divalent 1,4-benzene radical (-1,4-(C₆H₄)—) remaining after removal of the carboxylic groups from terephthalic acid-. The term “isophthalic acid group” refers to a divalent 1,3-benzene radical (-(-1,3-C₆H₄)—) remaining after removal of the carboxylic groups from isophthalic acid. The term “adipic acid group refers to a divalent butane radical (—C₄H₈—) remaining after removal of the carboxylic groups from adipic acid. The “butanediol group” refers to a divalent butylene radical (—(C₄H₈)—) remaining after removal of hydroxyl groups from butanediol. For example, the term “ethylene glycol group” refers to a divalent ethylene radical (—(C₂H₄)—) remaining after removal of hydroxyl groups from ethylene glycol. With respect to the terms “terephthalic acid group,” “isophthalic acid group,” “ethylene glycol group,” and “butane diol group,” being used in other contexts, e.g., to indicate the weight % of the group in a composition, the term “isophthalic acid group(s)” means the group having the formula (—O(CO)C₆H₄(CO)—), the term “terephthalic acid group” means the group having the formula (—O(CO)C₆H₄(CO)—), the term “butanediol group” means the group having the formula (—O(C₄H₈)—), and the term “ethylene glycol groups” means the group having formula (—O(C₂H₄)—).

Unless otherwise specified, all molar amounts of isophthalic acid groups, terephthalic acid groups, adipic acid groups, and/or other acid groups are based on the total moles of diacids/diesters in the composition. Unless otherwise specified, all molar amounts of the butanediol, ethylene glycol, diethylene glycol groups or other diol groups are based on the total moles of diol in the composition. The weight percent measurements stated above are based on the way terephthalic acid groups, isophthalic acid groups, ethylene glycol groups, and the like have been defined herein.

The heat-resistant resistant aromatic polyester resin, specifically a thermoplastic polymer, has a melting point temperature of at least 260° C. Examples of heat-resistant aromatic polyesters include polyester resins of which at least 80 mole percent, specifically at least 90 mole percent, and most specifically all of the diol repeat units are derivable from 1,4-cyclohexanedimethanol (or its chemical equivalent) and are of the formula (I):

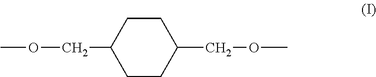

and at least about 80 mole percent, more specifically at least about 90 mole percent, and most specifically all of the dicarboxylic acid repeat units are derivable from terephthalic acid (or its chemical equivalent) and are of the formula (II):

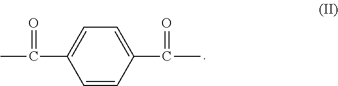

The diol and dicarboxylic acid repeat units can represent more than 90 weight percent of the polyester, specifically more than 98 wt. % of the polyester, most specifically 100 weight percent of the polyester. The polyester can optionally also contain other diol or dicarboxylic acid repeat units, for example, hydroxycarboxylic acids, isophthalic acid, and ethylene glycol, each in amounts not more than 20 mole percent, specifically not more than 10 mole percent.

The organic resin can, therefore, include, for example poly(1,4-cyclohexylenedimethylene) terephthalate (PCT) and poly(1,4-cyclohexylene dimethylene terephthalate-co-isophthalate) (PCTA). Other useful polyesters are copolyesters derived from an aromatic dicarboxylic acid and a mixture of linear aliphatic diols (specifically ethylene glycol or butylene glycol) together with 1,4-cyclohexane dimethanol and its cis- and trans-isomers. The ester units comprising the linear aliphatic or cycloaliphatic ester units can be present in the polymer chain as individual units, or as blocks of the same type of units. A specific ester of this type is poly(1,4-cyclohexylene dimethylene co-ethylene terephthalate) (PCTG). For high heat-resistance, 80 mole percent or more of the ester groups can be derived from 1,4-cyclohexanedimethanol.

In one aspect of the invention, specific polymers can be selected based on having a melting point or transition temperature of at least 260° C.

In one embodiment, the heat-resistant aromatic polyester is dimensionally stable above 80° C. and below 0° C. Such polyesters can be formed from a repeating condensation reaction in which the condensation of monomers involves at least one aromatic group. Specifically, high temperature resistant aromatic polyesters are used that have a heat deflection temperature (HDT) above 80° C., specifically above 100° C. to 250° C., more specifically above 110° C. to 200° C., under a load of 1.82 MPa measured according to ASTM D648.

The heat resistant aromatic polyester can be a PCT (including PCT, PCTA and PCTG).

For example, resin compositions based on poly(cyclohexyldimethylene terephthalate) (PCT) have been found advantageous. Other suitable resin compositions are poly(1,4-cyclohexylene dimethylene terephthalate-co-isophthalate) (PCTA) and poly(1,4-cyclohexylene dimethylene co-ethylene terephthalate) (PCTG) wherein greater than 50 mol % of the ester groups are derived from 1,4-cyclohexanedimethanol.

Cyclohexane dicarboxylic acids and their chemical equivalents can be prepared, for example, by the hydrogenation of cycloaromatic diacids and corresponding derivatives such as isophthalic acid, terephthalic acid or naphthalenic acid in a suitable solvent such as water or acetic acid using a suitable catalysts such as rhodium supported on a carrier such as carbon or alumina. They can also be prepared by the use of an inert liquid medium in which a phthalic acid is at least partially soluble under reaction conditions and with a catalyst of palladium or ruthenium on carbon or silica.

Typically, in the hydrogenation, two isomers are obtained in which the carboxylic acid groups are in cis- or trans-positions. The cis- and trans-isomers can be separated by crystallization with or without a solvent, for example, using n-heptane, or by distillation. The cis- and trans-isomers have different physical properties and can be used independently or as a mixture. Mixtures of the cis- and trans-isomers are useful herein as well.

When a mixture of isomers or more than one diacid or diol is used, a copolyester or a mixture of two polyesters can be used as the cycloaliphatic polyester.

Chemical equivalents of these diacids can include esters, alkyl esters, e.g., dialkyl esters, diaryl esters, anhydrides, salts, acid chlorides, acid bromides, and the like. In one embodiment the chemical equivalent comprises the dialkyl esters of the cycloaliphatic diacids, and most specifically the chemical equivalent comprises the dimethyl ester of the acid, such as dimethyl-1,4-cyclohexane-dicarboxylate.

The polyester polymerization reaction can be run in melt in the presence of a suitable catalyst such as a tetrakis(2-ethyl hexyl) titanate, in a suitable amount, generally 50 to 200 ppm of titanium based upon the total weight of the polymerization mixture.

Also contemplated herein are mixtures of a first and second polyester such that the mixture has a melting point temperature of at least 260° C. Thus, lesser amounts of lower melting polyesters as a second organic resin can be used.

For example, in addition to poly(cyclohexyldimethylene terephthalate) (PCT) as the first or primary organic resin, lesser amounts of other polyesters such as poly(ethylene terephthalate)-co-(1,4-cyclohexyldimethylene terephthalate), abbreviated as PETG where the polymer comprises greater than 50 mole % of ethylene terephthalate ester units, and abbreviated as PCTG where the polymer comprises greater than 50 mole % of 1,4-cyclohexyldimethylene terephthalate ester units. In one embodiment, the poly(ethylene terephthalate)-co-(1,4-cyclohexyldimethylene terephthalate) comprises 10 to 90 mole percent ethylene terephthalate units and 10 to 90 mole percent 1,4-cyclohexyldimethylene terephthalate units.

The polyesters can be obtained by interfacial polymerization or melt-process condensation, by solution phase condensation, or by transesterification polymerization wherein, for example, a dialkyl ester such as dimethyl terephthalate can be transesterified with 1,4-butane diol using acid catalysis, to generate poly(1,4-butylene terephthalate). It is possible to use a branched polyester in which a branching agent, for example, a glycol having three or more hydroxyl groups or a trifunctional or multifunctional carboxylic acid has been incorporated. Furthermore, it is sometime desirable to have various concentrations of acid and hydroxyl end groups on the polyester, depending on the ultimate end use of the composition. The polyesters described herein are generally completely miscible with the polyester-polycarbonate polymers when blended.

The polyesters used as the heat-resistant aromatic polyester, specifically a cycloaliphatic polyester, can have an intrinsic viscosity of 0.4 to 2.0 deciliters per gram (dL/g), measured in a 60:40 by weight phenol/1,1,2,2-tetrachloroethane mixture at 23° C. The polyesters can have a weight average molecular weight of 10,000 to 200,000 Daltons, specifically 50,000 to 150,000 Daltons, more specifically about 25,000 Daltons to about 85,000 Daltons, as measured by gel permeation chromatography (GPC). The polyesters can also comprise a mixture of different batches of polyesters prepared under different process conditions in order to achieve different intrinsic viscosities and/or weight average molecular weights. In one embodiment, the weight average molecular weight is about 30,000 Daltons to about 80,000 Daltons and most specifically about 50,000 to about 80,000 Daltons.

The present resin composition can comprise heat-resistant aromatic polyester having a melting point temperature of at least 260° C., specifically a polycondensation polymer, more specifically a polyester such as cycloaliphatic polyester in an amount from 20 to 90 weight percent, based on the total weight of the resin composition, specifically at least 25 weight percent, even more specifically in an amount of at least 30 weight percent of the resin composition. In one embodiment, the heat-resistant aromatic polyester is present in an amount of 25 to 80 weight percent, based on the total weight of the composition, specifically 30 to 70 weight percent, even more specifically 35 to 75 weight percent, each based on the total weight of the resin composition. Based on the polymer content of the composition, the heat-resistant aromatic polyester can be used in an amount of at least 40 wt. %, specifically 55 wt. % to 90 wt. %.

The thermoplastic composition optionally further comprises one or more additional polymers, i.e. second organic resins, in an amount of between 1 and 50 wt. %, based on the total weight of the composition and 2 to 49 wt. % based on the total weight of resin in the composition. Specifically, the second polymer is an aromatic polymer, more specifically a polymer that comprises terephthalic acid units (i.e. having repeat units derived from the monomer).

The first organic resin, the heat-resistant aromatic polyester, can be admixed or blended with lesser amounts of a second organic resin, differing with respect to at least one kind of monomer unit. Specifically, the second organic resin is miscible in the first organic resin. For example, a second polyester can comprise diol units different from the diol units of the first polyester. For example, a cycloaliphatic polyester such as PCT polyester can be blended with a second organic resin selected from the group consisting of polyesters comprising butanediol repeat units, polyesters comprising 2,2,4,4-tetramethyl-1,3-cyclobutanediol units, and polyamides comprising terephthalic acid. Specifically, the cycloaliphatic polyester can be combined with lesser amounts of a polyester such as polybutylene terephthalate, polypropylene terephthalate, or a copolyester polymer produced from dimethyl terephthalate, 1,4-cyclohexanedimethanol, and 2,2,4,4-tetramethyl-1,3-cyclobutanediol (TRITAN copolyester from Eastman Chemical Co.), or combinations thereof, or a polyamide such as polyamide 9T or polyphthalamide (PPA).

To obtain a white reflector, titanium dioxide, a white inorganic filler, is mixed with the heat-resistant aromatic polyester, for example, a cycloaliphatic aromatic polyester. Other white inorganic fillers, in addition to titanium dioxide, that can contribute to the reflectivity of the resin composition can include potassium titanate, zirconium oxide, zinc sulfide, zinc oxide, magnesium oxide, alumina, antimony oxide, aluminum hydroxide, barium sulfate, magnesium carbonate, barium carbonate, or the like, and mixtures thereof. In one embodiment, not more than about 3 wt. % of metallic carbonates is present in the composition. Specifically, the presence of more than 1 wt. % of metallic carbonates is excluded, and specifically no calcium carbonate is present in the composition. At least 90 wt. % of the whiter inorganic filler, specifically at least about 97 wt. % can be titanium dioxide. The oxide of an element selected from magnesium, zinc or aluminum can also be used. The unit lattice of titanium dioxide can be of any one of the rutile type, anatase type, and brookite type. Specifically, the rutile type can be used. In one embodiment, the titanium dioxide has an inorganic surface treatment that is alumina and an organic surface treatment that is a polysiloxane. One such coated titanium dioxide is commercially available under the brand name Kronos® 2233 from Kronos, Inc. (USA), which can provide pure, brilliant tones and high tinting strength.

No particular limitation is imposed on the average particle size or shape of titanium dioxide to be used as a white pigment. The titanium dioxide can be surface treated with a hydroxide of Al or Si to improve its compatibility with, and dispersibility in, the resin, as long as the surface treatment does not adversely affect the reflectivity of the material to which it is added.

In one embodiment, a mixture of white pigments (white colorant) can be used, for example titanium dioxide in combination with potassium titanate, zirconium oxide, zinc sulfide, zinc oxide, magnesium oxide, and combinations thereof.

Other inorganic fillers that can be incorporated in the resin composition include, for example, silicas such as fused silica, fused spherical silica and crystalline silica, alumina, silicon nitride, aluminum nitride, and boron nitride. No particular limitation is imposed on the average particle size or shape of such an additional inorganic filler, but the average particle size can generally be 4 to 40 μm, specifically 7 to 35 μm. The inorganic filler can also include an oxide of a rare earth element (“rare earth element oxide”) as one component. The term “rare earth elements” is a generic term for 18 elements that includes lanthanoid elements belonging to Group III of the periodic table and ranges from atomic numbers 57 to 71 (lanthanum, cerium, praseodymium, neodymium, promethium, samarium, europium, gadolinium, terbium, dysprosium, holmium, erbium, thulium, ytterbium and lutetium), and further, atomic numbers 21, 39 and 49 of the same Group III, i.e., scandium, yttrium and indium. Specific rare earth element oxides are oxides of yttrium, neodymium, indium, lanthanum, cerium, samarium, europium, gadolinium and dysprosium. Rare earth element oxides such as yttrium oxide, lanthanum oxide, cerium oxide, neodymium oxide, samarium oxide, europium oxide, gadolinium oxide, dysprosium oxide, and indium oxide can efficiently reflecting light equal to or smaller than 500 nm

To increase photo-reflectance, it is desirable that the inorganic filler be evenly dispersed in the composition. With moldability and flowability in view, the average particle size can be 0.05 to 60 micrometer, more specifically 0.5 to 50 micrometers, still more specifically 0.5 to 5 micrometers. The average particle size can be determined as a weight average diameter D₅₀ (or median size) in a particle size distribution measurement by laser diffraction analysis.

The proportion of the white inorganic filler, and specifically titanium dioxide filler, can be 5 to 50% by weight, more specifically 10 to 40% by weight, still more specifically 12 to 30% by weight based on the total composition. An excessively small proportion of the white inorganic filler can provide the resulting reflector with a lowered photo-reflectance so that a light-emitting semiconductor unit would be unable to produce sufficient brightness in some instances, whereas an unduly large proportion of the white inorganic filler, on the other hand, can lead to a reduction in flowability due to increased melt viscosity of the resin composition such that short molding can inconveniently arise upon molding the reflector.

For providing the resulting reflector with enhanced heat resistance, strength, or other properties, it is possible to incorporate still other fillers, white or otherwise. Such fillers can include mica, talc, calcium silicate, silica, clays such as kaolin, and the like.

To enhance the bond strength between the resin and the white inorganic filler, the white inorganic filler can be surface treated with a coupling agent such as a silane coupling agent or titanate coupling agent.

Examples of such coupling agents include epoxy-functional alkoxysilanes such as γ-glycidoxypropyltrimethylsilane, γ-glycidoxypropyl-methyldiethoxysilane and β-(3,4-epoxycyclohexyl)ethyltrimethoxysilane, amino-functional alkoxysilanes such as N-β-(aminoethyl)-7-aminopropyltrimethoxysilane, 7-aminopropyl-triethoxysilane and N-phenyl-7-aminopropyltrimethoxysilane, and mercapto-functional alkoxy silanes such as γ-mercaptopropyltrimethoxysilane. No particular limitation is imposed on the amount of the coupling agent to be used, if any, in the surface treatment or on the method of the surface treatment.

The whiteness of the composition in the reflector can be 80% or higher, more specifically in the range from 85% to 100%, and further specifically from 87% to 100%. As this whiteness becomes higher, the light reflective characteristic from an LED element is more excellent. The whiteness can be measured with a Hunter color difference meter. The whiteness can be adjusted by selecting, as appropriate, the type and content of the specific resins in the composition, the type, shape and content of the white inorganic filler, the type, shape and content of the glass fiber, the type and content of any optional coloring agent, and the like.

The resin composition comprises from greater than zero to about 50 wt. %, based on the weight of the entire composition, of a reinforcing fiber having a flat surface, resulting in a non-circular cross-section. In particular, flat glass fibers can be employed in an amount from about 10 wt. % to about 40 wt. %, or about 10 wt. % to about 30 wt. % based on the weight of the entire composition. The flat glass fibers can be present in an amount over 20 weight percent, specifically at least 22 weight percent, more specifically at least about 25 weight percent, based on the total composition. Flat glass fibers typically can have a modulus of greater than or equal to about 6,800 megaPascals and can be chopped or continuous. The flat glass fiber can have various cross-sections, for example, trapezoidal, rectangular, or square, crescent, bilobal, trilobal, and hexagonal.

In preparing the molding compositions it is convenient to use a glass fiber in the form of chopped strands (upon introduction into the resin composition, before compounding) having an average length of from 0.1 mm to 10 mm, specifically 0.2 to 5 mm, and having an average aspect ratio of 1 to 5.0 (1:1 to 5:1) in cross-section, specifically 1.5 to 4.5, more specifically 2.2 to 4.2, wherein dimensions prior to the compounding process are provided. The equivalent circular diameter of the fibers can be 3 to 30 micrometers, specifically 5 to 25, more specifically 7 to 20 micrometers. In one embodiment, the longest diameter is 10 to 50 micrometers, specifically, 20 to 40 micrometers, and the shortest diameter is 1 to 15, specifically 4 to 12 micrometers in diameters. In articles molded from the compositions, on the other hand, shorter lengths will typically be encountered because considerable fragmentation can occur during compounding. Flat glass fiber is commercially available from Nittobo Boseki Co., Ltd., for example, CSG3PA-830. Flat glass fiber is also commercially available from CPIC (Chongquing Polycomp International Corp.), for example ECS 301T and 3012T glass fibers.

In some applications it can be desirable to treat the surface of the fiber with a chemical coupling agent to improve adhesion to a thermoplastic resin in the composition. Examples of useful coupling agents for the glass fibers are alkoxy silanes and alkoxy zirconates. Amino, epoxy, amide, or thio functional alkoxy silanes are also useful. Fiber coatings with high thermal stability are preferred to prevent decomposition of the coating, which could result in foaming or gas generation during processing at the high melt temperatures required to form the compositions into molded parts.

In one embodiment, essentially no rounded or rod-shaped glass fibers are present in the composition. In another embodiment, the fibrous reinforcing filler consists of flat glass fibers, i.e., the only fibrous reinforcing filler present is the flat glass fibers.

Additional fibers can be optionally present. For example, in addition to the required glass fibers, for example, other fibers can include rock wool, synthetic polymeric fibers, aluminum fibers, aluminum silicate fibers, oxide of metals such as aluminum fibers, titanium fibers, magnesium fibers, wollastonite, rock wool fibers, steel fibers, tungsten fibers, alumina fibers, boron fibers, etc. Polymeric fibers can include fibers formed from engineering polymers such as, for example, poly(benzothiazole), poly(benzimidazole), polyarylates, poly(benzoxazole), polyaryl ethers, or aromatic polyamide fibers such as the fibers sold by the DuPont Company under the trade name KEVLAR, and the like, and can include mixtures comprising two or more such fibers. Heat conductive particles are optionally present in the resin composition.

With the proviso that reflectivity properties, heat resistance, and mechanical properties such as impact strength, tensile modulus and flexural modulus are not adversely affected to an undue degree, the compositions can optionally further comprise conventional additives used in similar polymer compositions such as stabilizers including antioxidants, light (radiation) stabilizers such as ultraviolet light absorbing additives, mold release agents, quenchers, and nucleating agents. A combination comprising one or more of the foregoing or other additives can be used. These additives can be used in a total amount of 0.01 to 20 wt. %, specifically 0.1 to 10 wt. %, more specifically 1 to 5 wt. %, which is exclusive of the white inorganic filler and glass fibers described above and total polymers in the resin composition.

For example, the composition can contain a mold release agent. Mold release agents include, but are not limited to, pentaerythritol tetracarboxylates, glycerol monocarboxylates, polyolefins, alkyl waxes and amides.

The composition can also comprise a quencher. An acidic quencher can further neutralize the basicity of titanium dioxide filler, which can stabilize the composition. Hence, a quencher is sometimes referred to as an acid stabilizer. The addition of an acidic quencher or its salt or ester can deactivate catalytically active species such as alkali metals. This can also reduce the amount of degradation of polymers. The identity of the quencher is not particularly limited. Suitable quenchers include acids, acid salts, esters of acids or their combinations. Particularly useful classes of quenchers, including acids, acid salts, and esters of acids are those derived from a phosphorous containing acid such as phosphoric acid, phosphorous acid, hypophosphorous acid, hypophosphoric acid, phosphinic acid, phosphonic acid, metaphosphoric acid, hexametaphosphoric acid, thiophosphoric acid, fluorophosphoric acid, difluorophosphoric acid, fluorophosphorous acid, difluorophosphorous acid, fluorohypophosphorous acid, fluorohypophosphoric acid or their combinations. In one embodiment, a combination of a phosphorous containing acid and an ester of a phosphorous containing acid is used. Alternatively, acids, acid salts and esters of acids, such as, for example, sulphuric acid, sulphites, mono zinc phosphate, mono calcium phosphate, and the like, may be used. The quencher can be an inorganic acidic phosphorus-containing compound. In particular embodiments, the quencher is phosphorous acid (H₃PO₃), phosphoric acid (H₃PO₄), mono zinc phosphate (Zn₃(PO₄)₂), mono sodium phosphate (NaH₂PO₄), or sodium acid pyrophosphate (Na₂H₂P₂O₇). The weight ratio of quencher to titanium dioxide filler can be from about 0.005 to 0.05, specifically 0.01 to about 0.03.

The compositions can comprise an antioxidant stabilizer, for example a hindered phenol stabilizer, a thioether ester stabilizer, an amine stabilizer, a phosphite stabilizer, a phosphonite stabilizer, or a combination comprising at least one of the foregoing types of stabilizers.

Exemplary phosphites include organophosphites such as tris(2,6-di-tert-butylphenyl)phosphite, tris(nonyl phenyl)phosphite, tris(2,4-di-t-butylphenyl)phosphite, bis(2,4-di-t-butylphenyl)pentaerythritol diphosphite, distearyl pentaerythritol diphosphite or the like.

Exemplary hindered phenols can include alkylated monophenols or polyphenols; alkylated reaction products of polyphenols with dienes, such as tetrakis[methylene(3,5-di-tert-butyl-4-hydroxyhydrocinnamate)]methane, commercially available from Ciba Geigy Chemical Company as IRGANOX® 1010; butylated reaction products of para-cresol; alkylated hydroquinones; hydroxylated thiodiphenyl ethers; alkylidene-bisphenols; esters of beta-(3,5-di-tert-butyl-4-hydroxyphenyl)-propionic acid with monohydric or polyhydric alcohols; octadecyl-3-(3,5-di-tert-butyl-4-hydroxyphenyl)propionate, pentaerythrityl-tetrakis[3-(3,5-di-tert-butyl-4-hydroxyphenyl)propionate, and esters of beta-(5-tert-butyl-4-hydroxy-3-methylphenyl)-propionic acid with monohydric or polyhydric alcohols.

Exemplary thioether esters can include C₄₋₂₀ alkyl esters of thiodipropionic acid, including distearyl thiodipropionate, dilaurylthiodipropionate, and ditridecylthiodipropionate. U.S. Pat. Nos. 5,057,622 and 5,055,606 describe examples of thioether esters. Still other thioether ester stabilizers include C₄₋₂₀ alkyl esters of beta-laurylthiopropionic acid, including pentaerythritol tetrakis(beta-lauryl thiopropionate). Other esters of thioalkyl or thioaryl compounds can include octadecyl-3-(3,5-di-tert-butyl-4-hydroxyphenyl)propionate, pentaerythrityl-tetrakis[3-(3,5-di-tert-butyl-4-hydroxyphenyl)propionate, or the like. A specific thioether ester is pentaerythritol tetrakis(3-(dodecylthiopropionate), also referred to as pentaerythritol tetrakis(beta-lauryl thiopropionate) sold under the trade name SEENOX™ 412S and commercially available from Crompton Corporation.

Amide stabilizers can include, for example, amides of beta-(3,5-di-tert-butyl-4-hydroxyphenyl)-propionic acid or the like.

Exemplary phosphonites can include organophosphonites, for example, tetrakis(2,4-di-tert-butylphenyl) 4,4′-biphenylene diphosphonite, which is available under the trade name SANDOSTAB® P-EPQ from Sandoz AG or Clariant. The stabilizers can be combined to form stabilizer compositions or packages. In one embodiment, the stabilizer composition comprises a stabilizer selected from the group consisting of thioether esters, hindered phenols, organophosphites, organophosphonites, quenchers, and combinations thereof.

A stabilizer package (stabilizer composition) can contain, for example, an organophosphonite antioxidant, a thioether ester antioxidant, and a quencher. The stabilizer package can further comprise a mold release agent, which can assist in stabilization, for example, pentaerythritol tetrastearate. An exemplary stabilizer composition comprises an organophosphonite, a thioether ester, and a quencher, each in a weight ratio of 80:20 to 20:80, specifically 70:30 to 30:70 based on the weight of the stabilizer composition. Specifically the stabilizer composition can comprises tetrakis(2,4-di-tert-butylphenyl) 4,4′-biphenylene diphosphonite, pentaerythrityl-tetrakis(beta-lauryl thiopropionate), and a quencher.

When present, the quenchers and antioxidants (each or in total amount) can be used in an amount of 0.01 wt. % to 5 wt. %, more specifically 0.1 wt. % to 3 wt. %, more specifically 0.1 to 2 wt. %, based on the total weight of the thermoplastic composition.

Exemplary light stabilizers including ultraviolet light (UV) absorbing additives include, for example, benzotriazoles such as 2-(2-hydroxy-5-methylphenyl)benzotriazole, 2-(2-hydroxy-5-tert-octylphenyl)-benzotriazole and 2-hydroxy-4-n-octoxy benzophenone, or the like, or combinations comprising at least one of the foregoing light stabilizers. Light stabilizers can be used in amounts of 0.0001 to 1 weight percent, based on the total weight of the composition. Exemplary UV absorbing additives include for example, hydroxybenzophenones; hydroxybenzotriazoles; hydroxybenzotriazines; cyanoacrylates; oxanilides; benzoxazinones; 2-(2H-benzotriazol-2-yl)-4-(1,1,3,3-tetramethylbutyl)-phenol (CYASORB® 5411); 2-hydroxy-4-n-octyloxybenzophenone (CYASORB® 531); 2-[4,6-bis(2,4-dimethylphenyl)-1,3,5-triazin-2-yl]-5-(octyloxy)-phenol (CYASORB® 1164); 2,2′-(1,4-phenylene)bis(4H-3,1-benzoxazin-4-one) (CYASORB® UV-3638); 1,3-bis[(2-cyano-3,3-diphenylacryloyl)oxy]-2,2-bis[[(2-cyano-3,3-diphenyl-acryloyl)oxy]methyl]propane (UVINUL® 3030); 2,2′-(1,4-phenylene)bis(4H-3,1-benzoxazin-4-one); 1,3-bis[(2-cyano-3,3-diphenylacryloyl)oxy]-2,2-bis[[(2-cyano-3,3-diphenyl-acryloyl)oxy]methyl]propane; nano-size inorganic materials such as titanium oxide, cerium oxide, and zinc oxide, all with particle size less than 100 nanometers; or the like, or combinations comprising at least one of the foregoing UV absorbers. UV absorbers can be used in amounts of 0.0001 to 1 weight percent, based on the total weight of the composition.

The composition can further include a material capable of increasing the heat deflection temperature of the composition. Such materials can include inorganic and organic materials that function as nucleating agents and help increase the heat deflection temperature (HDT) when used in small amounts, e.g., 1 wt. % or less. Such a material can be selected, for example, from the group of talcs having fine particles, clays, mica, and combinations thereof, as well as other materials capable of functioning as nucleating agents. The ranges of such materials can vary from 0.01 to 3 wt. %. In an embodiment, the range of such materials can range from 0.1 to 2 wt. %.

Total additives, (including quenchers, antioxidants, mold release agents, light stabilizers, and nucleating agents) can be used in an amount of 0.01 wt. % to 10 wt. %, more specifically 0.1 wt. % to 6 wt. %, more specifically 0.5 to 4 wt. %, based on the total weight of the thermoplastic composition.

The suitability of a particular compound for use as a stabilizer, alone or in combination with other stabilizers, and the determination of how much is to be used as a stabilizer can be readily determined by preparing a mixture of the thermoplastic composition and determining the effect on melt viscosity, color stability, the formation of interpolymer, or other relevant properties.

In one especially exemplary embodiment, the composition comprises PCT polyester, flat glass fiber, titanium dioxide and a stabilizer composition selected from the group consisting of thioether ester stabilizers, hindered phenol stabilizers, amine stabilizers, phosphonite stabilizers, quenchers, and combinations thereof. Specifically, the composition can comprises from about 0.1 wt. % to 5 wt. % of a stabilizer composition comprising at least about 0.1 wt. % to 2 wt. % of a quencher, 0.1 to 2 wt. % of a thioether ester having a molecular weight of greater than 500 Daltons, and 0.1 to 2 wt. % of at least one additional stabilizer that is selected from the group consisting of hindered phenols, organophosphites, organophosphonites, and combinations thereof. In one embodiment the thioether ester is a C₄₋₂₀ alkyl ester of a thioether acid, for example an ester of thiodipropionic acid, more specifically an ester of 3-laurylthiopropionic acid.

The compositions can be prepared by blending the components of the composition, employing a number of procedures. In an exemplary process, the heat-resistant aromatic polyester component, inorganic filler component, glass fiber component, and optional additives are put into an extrusion compounder to produce molding pellets. The other ingredients are dispersed in a matrix of the one or more organic resins in the process. In another procedure, the ingredients, including glass fiber, are mixed with the organic resins by dry blending and then fluxed on a mill and comminuted, or extruded and chopped. The composition and any optional ingredients can also be mixed and directly molded, e.g., by injection or transfer molding techniques. The ingredients can be freed from as much water as desired. In addition, compounding can be carried out to ensure that the residence time in the machine is short; the temperature is carefully controlled; the friction heat is utilized; and an intimate blend between the resin composition and any other ingredients is obtained.

In one embodiment, the ingredients are pre-compounded, pelletized, and then molded, wherein pre-compounding is carried out, after pre-drying the polyester composition (e.g., for four hours at 120° C.), in a single screw extruder fed with a dry blend of the ingredients, the screw employed having a long transition section to ensure proper melting. Alternatively, a twin screw extruder with intermeshing co-rotating screws can be fed with organic resin, inorganic filler, and additives at the feed port and glass fibers (and other additives) can be fed downstream. A suitable melt temperature for the composition is 230° C. to 300° C. The pre-compounded composition can be extruded and cut up into molding compounds such as conventional granules, pellets, and the like by standard techniques. The composition can then be molded in any equipment conventionally used for thermoplastic compositions, such as a Newbury or van Dorn type injection molding machine. A mold temperature of 55° C. to 150° C. can be used. The molded compositions can provide an excellent balance of impact strength and flame retardancy.

As the most general process for molding reflectors with the resin composition, low-pressure transfer molding or compression molding can be mentioned. The molding of the resin composition according to the present invention can desirably be performed at 130 to 300° C. for 30 to 180 seconds.

As mentioned previously, the resin composition according to the present invention can be used for the molding of a reflector for a light-emitting semiconductor unit. For such application, the resin composition can be molded and cured into the form of a reflector. In one embodiment, a method for the manufacture of the resin composition comprises blending the components of the composition, including the step of adding one or more of the inorganic fillers in sufficient amounts to produce a composition having a white appearance.

The photo-reflectance at 350 to 750 nm of a product obtained by molding the resin composition according to the present invention, which contains the above-described components, can be 80% or higher as an initial value. A reflectance of 90% or higher at a wavelength greater than 440 nm is more desired. Specifically, a molded article comprising the composition can have a reflectance at 460 nm of 80 to 98 percent, specifically at least 88, more specifically at least 90 or 91. A molded article comprising the composition can have a reflectivity in the range from 380 nm to 750 nm of 80 to 98 percent, specifically at least 90 percent, more specifically at least 91 or 93 percent.

A molded article comprising the composition can have a melt volume rate at 300 C of from 15 to 60 cm3/10 minutes, in accordance with ASTM D 1238, a flexural modulus of from 3000 MPa to 20000 MPa, measured in accordance with ASTM 790, and flexular stress at break of from 120 to 200 MPa, more specifically 130 to 190 MPa, measured in accordance with ASTM 790.

A molded article comprising the composition can also have good impact properties, for example, a molded article comprising the composition can have a notched Izod impact strength from to 30 to 80 J/m, measured at 23° C. in accordance with ASTM D256. The composition can further have good tensile properties. A molded article comprising the composition can have a tensile modulus of elasticity from 2000 MPa to 15000 MPa, measured in accordance with ASTM 790. A molded article comprising the composition can have a tensile stress at break from to 80 to 150 MPa, measured in accordance with ASTM 790.

A molded article comprising the composition can have a heat deflection temperature from 150° C. to 270° C., specifically 195° C. to 260° C., most specifically about 240 to 250° C., measured in accordance with ASTM D648 at 1.82 MPa. In a specific embodiment, the compositions can have a combination of highly useful physical properties. For example, a molded article comprising the composition can have a notched Izod impact strength from to 30 to 80 J/m, measured at 23° C. in accordance with ASTM D256, and a heat deflection temperature from 195° C. to 260° C., measured in accordance with ASTM D648 at 1.82 MPa.

In one embodiment, one or more of the foregoing properties can be achieved by a composition in which the organic resin consists of poly(1,4-cyclohexanedimethylene terephthalate) (PCT) or PCT in combination with lesser amounts of another polyester or polyamide.

Also disclosed are molded articles that comprise the resin composition, such as electric and electronic parts, specifically a reflector for a light-emitting semiconductor diode. The article can be formed by molding the resin composition to form the article. Injection molded articles are specifically mentioned, for example, reflectors for an LED unit that are injection molded.

The reflector can be any reflector for reflecting light from a light-emitting semiconductor element (or “chip”). The reflector's shape can be selectively determined depending on the details of the light-emitting semiconductor unit.

The reflector of the present invention has the function of reflecting mainly light from the LED element on the inside surface thereof, toward a lens. Reflectors can have a cylindrical, annular or other shape. In cross-section, for example, the reflector can be square-shaped, circular, oval, or ellipse-shaped. The inner surfaces of the reflector can be tapered to point outward as they extend upward in order to increase the degree of directivity of light from the LED element. Other shapes are parabaloidal, conical, and hemispherical. Reflectors can also be shaped to support the end portions of a lens.

Examples of reflectors include both flat-plate reflectors and recessed reflectors. The reflector can be integrally formed with other components of an LED unit, for example, a single component can form a reflector portion and a substrate portion under the LED chip.

A recessed reflector can be configured as a ring-shaped wall member and can be arranged on leads via which electrodes of the light-emitting semiconductor chip and external electrodes are connected together, respectively. (The current through the light-emitting semiconductor chip typically flows from the p-side, or anode, to the n-side, or cathode.) The reflector material can also be configured to fill up space between the leads in continuation with the ring-shaped wall member.

A further aspect of the invention is directed to a light-emitting semiconductor package comprising a reflector and a solder, wherein the reflector comprises a resin composition comprising about 25 to about 80 wt. % of an heat-resistant aromatic polyester have a melting point temperature higher than the point of the solder about 5 to 50 wt. % of a white inorganic filler; and about 5 to 50 wt. % of glass fiber having a flat surface. The package is defined to mean a printed circuit board including at least one, specifically a plurality of, solderable devices. The solderable device can be an LED unit. The resin composition in the package can have a melting point below 260° C. so long as the solder melts below 260° C. While less common than higher melting lead solders, such low melting solders can advantageously cause less damage to a device and allow a reduction in electric power in a reflow process. Conventional low-temperature solders can, for example, include Sn—Bi—Pb, Sn—Bi—Cd, Sn—Pb—Bi, Sn—In, Sn—Bi, Sn—Pb—Cd, Sn—Cd alloys, as described in U.S. Pat. No. 8,303,735, ranging in melting point from 95 to 175° C. U.S. Pat. No. 8,303,735 discloses a lead-free low-temperature soldering alloy made of gold, tin and indium. In such a package, the heat-resistant aromatic polyester in the present composition can have a melting point temperature of less than 260° C. The heat-resistant aromatic polyester and resin composition is otherwise as described herein.

The present invention also provides a light-emitting semiconductor unit having a light-emitting semiconductor element, leads connecting electrodes of the light-emitting semiconductor element with external electrodes, respectively, and a reflector for the light-emitting semiconductor element composed of the resin composition according to the present invention. The light-emitting semiconductor chip can be sealed with a transparent resin or a phosphor-containing transparent resin, hereafter referred to as a transparent sealing resin or composition.

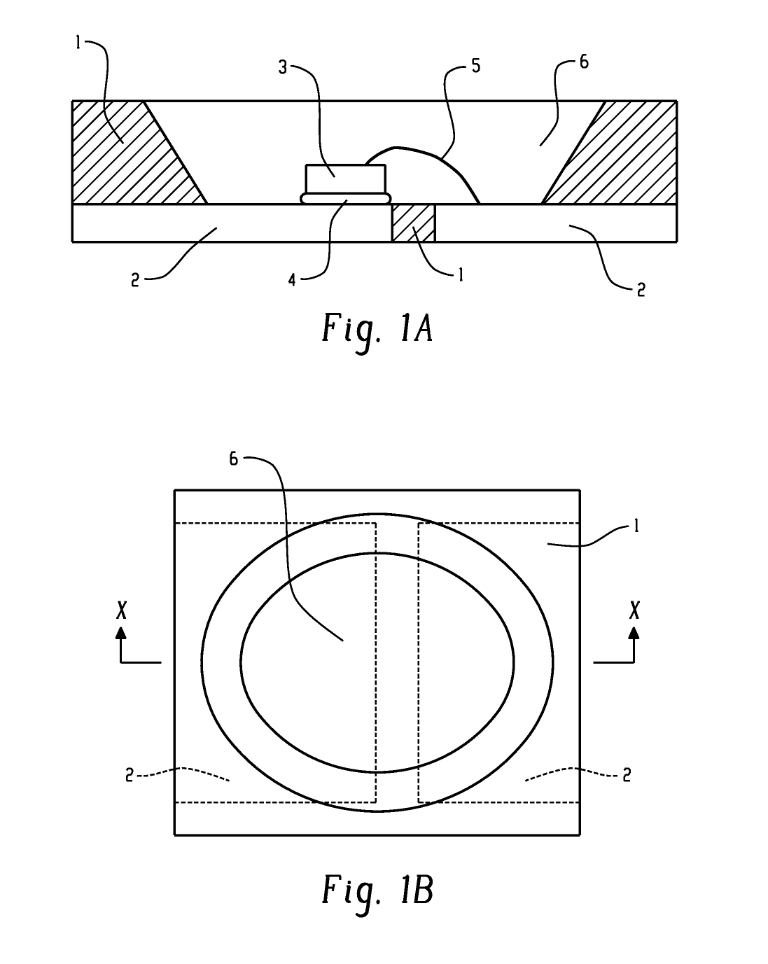

FIGS. 1A and 1B illustrate, by way of example, one embodiment of a reflector according to the present invention for a light-emitting semiconductor element and a light-emitting semiconductor unit making use of the reflector. In the figures, there are shown the reflector 1, a metal lead frame 2, the light-emitting semiconductor element 3, a die pad 4, conductive wire 5, and transparent sealing resin 6 that seals the light-emitting semiconductor element 3. The metal electrode frame 2 supports the die pad. The light-emitting semiconductor element or chip 3 is mounted on the die pad. The metal electrode frame 2 can connect the electrode of the semiconductor element 3 to external electrodes. The reflector 1 is in the form of a recessed body, which is composed of a substrate portion and a ring-shaped wall portion integrally molded together. A substrate portion is interposed between the die pad and the metal electrode frame 2. The ring-shaped wall portion forms a recessed reflector that accommodates therein the light-emitting semiconductor element 3 and wire 5.

The LED element can be a semiconductor chip (a light-emitting member) that emits light (UV or blue light in the case of a white light LED, in general) and has a double-hetero structure in which an active layer formed of, for example, AlGaAs, AlGaInP, GaP or GaN is sandwiched by n-type and p-type clad layers, as will be appreciated by the skilled artisan.

Individual reflectors can be discretely molded. Alternatively, as many as 300 reflectors can be molded such that they are arrayed in a matrix form.

During manufacture of the LED unit, heating can be conducted, for example, at 150° C. or more for one hour to fixedly secure a light-emitting semiconductor element onto a die pad. Subsequently, the light-emitting semiconductor element and inner ends of the metal electrode frame 2 can be electrically connected via the wires 5. Further, a transparent sealant composition with a phosphor incorporated therein can be cast into a recess of the reflector by potting, which is then heated and cured, for example, at 120° C. to 150° C. for an hour or more to seal the resulting light-emitting semiconductor unit.

The transparent sealant composition can convert the wavelength of light emitted from the LED element into a predetermined wavelength and can contain inorganic and/or organic fluorescent material. Examples of a transparent sealant composition that provides translucency and insulation can include generally a silicone, an epoxy silicone, an epoxy-based resin, an acryl-based resin, a polyimide-based resin, a polycarbonate resin and the like. Specifically, silicone is useful in terms of heat resistance, weather resistance, low contraction and resistance to discoloration. This transparent sealant can be a composition obtained by mixing a curable component of the above-mentioned components, a curing agent for curing the component, a curing catalyst as required and the like. The transparent sealant composition can contain a fluorescent material, a reaction inhibitor, an antioxidizing agent, a light stabilizer, a discoloration inhibitor and the like.

In the above-described examples, each light-emitting semiconductor chip and the inner ends of the corresponding leads are electrically connected via the wires. The connection method, however, is not limited to this method. For example, a light-emitting semiconductor chip and the inner ends of the corresponding leads can be connected by using bumps such as Au bumps or other means.

The invention is further illustrated by the following non-limiting examples.

### Examples

The following materials in Table 1 were used in the examples that follow.

TABLE 1

| Item | Component | Raw material description | CAS No. |
|---|---|---|---|
| A | PCT | Poly(cyclohexyldimethylene terephthalate) | 25135-20-0 |
| | | polyester from Eastman Chemical Co., polyester | |
| | | 13787, intrinsic viscosity 0.77 dl/g. | |
| B1 | PBT | Poly(butylene terephthalate), PBT 315 from | 26062-94-2 |
| | | Changchun Plastic Co., Ltd., intrinsic viscosity of | |
| | | 1.15-1.22 dl/g, specifically 1.2 dl/g, as measured | |
| | | in a 60:40 phenol/tetrachloroethane mixture at 23°. | |
| B2 | Copolyester | 1,4-benzenedicarboxylic acid, dimethyl ester, | NA |
| | | polymer with 1,4-cyclohexanedimethanol and | |
| | | 2,2,4,4-tetramethyl-1,3-cyclobutanediol, (Tritan ®) | |
| | | TX1000 from Eastman Chemical Co. | |
| B3 | PPA | Poly(propropylene terephthalate), | 27135-32-6 |
| | | AMODEL A 1006, from Solvay | |
| B4 | PA9T | Genestar ® GC61210 polyamide 9T from Kurary | 169284-22-4 |
| C | TiO₂ | Coated TiO₂, surface treatment with alumina and | 13463-67-7 |
| | | polysiloxane, Av. Diameter: 0.23 μm, Kronos ® | |
| | | 2233 from Kronos, Inc. | |
| D1 | Flat glass fiber | Flat glass fiber, Width: 28 μm/Height: 7 μm/ | 65997-17-3 |
| | | Length: 3 mm, CSG3PA-830 from Nittobo Boseki | |
| | | Co., Ltd. | |
| D2 | Circular glass fiber | 10 μm glass fiber | 65997-17-3 |
| D3 | Circular glass fiber | 13 μm glass fiber | 65997-17-3 |
| E | Talc | talc, Av. Diameter: 0.8 μm, from Microtuff AG 609 | 14807-96-6 |
| | | from Specialty Minerals, Inc. | |
| F | Phosphite stabilizer | Tris(2,4-di-tert-butylphenyl) phosphite | 31570-04-4 |
| G | Quencher | Mono zinc phosphate | 13598-37-3 |
| H | UV stabilizer | 2-(2-Hydroxy-5-tert-octylphenyl)benzotriazole, | 3147-75-9 |
| | | CYASORB UV 5411) | |
| I | Hindered phenol | Pentaerythritol tetrakis(3,5-di-tert-butyl-4- | 6683-19-8 |
| | stabilizer | hydroxyhydrocinnamate) | |
| J | Phosphonite | Tetrakis(2,4-di-tert-butylphenyl)-1,1-biphenyl-4,4′- | 38613-77-3 |
| | stabilizer | diylbisphosphonite, P-EPQ powder from Clariant | |
| K | Thioether ester | 2,2-Bis((3-(dodecylthio)-1- | 29598-76-3 |
| | stabilizer | oxopropoxy)methyl)propane-1,3-diyl bis(3- | |
| | | (dodecylthio)propionate), SEENOX 412S from | |
| | | Crompton Corp. | |
| L | Mold release agent | Pentaerythritol tetrastearate | 115-83-3 |

Testing: All testing, except flammability, followed ASTM protocols. Testing methods, standards and conditions are listed in Table 2.

TABLE 2

| | Standards | Testing Conditions |
|---|---|---|
| Melt Volume Rate (MVR) | ASTM D 1238 | 300° C., 1.2 kg |
| Uniaxial Tensile test | ASTM D638 | 50 mm/min |
| IZOD Impact Strength | ASTM D256 | 23° C., Notched, 5 lbf/ft |
| Heat Deflection | ASTM D648 | 0.45& 1.82 MPa, 3.2 mm |
| Temperature (HDT) | | |

The Melt Volume Rate (MVR (cm³/10 min)) of a polymer composition is a measure of the extrusion rate of the polymeric melt through a die with a specified length and diameter under set conditions of temperature and loads. This melt flow rate technique is based on the principle that flow increases with decreasing polymer viscosity for a given temperature and load test condition. A higher MVR value, therefore, indicates a lower viscosity under an applied stress (load or weight in kg) and generally increases as the molecular weight of a particular type of polymer decreases.

Tensile properties (Tensile Modulus (TM) (MPa), Tensile Stress (TS) (MPa) and Tensile Elongation (TE) (%)) were measured on molded samples having a thickness of 3.2 mm

Heat deflection temperature (HDT(1) is at 0.45 MPa, ° C. and HDT(2) is at 1.82 MPa, ° C.) was measured on molded samples having a thickness of 3.2 mm in accordance with ASTM 648.

Notched Izod testing (IZOD Impact Strength (23° C., Notched)) was performed on 75 mm×12.5 mm×3.2 mm bars in accordance with ASTM D256. Bars were notched prior to mechanical property testing and were tested at 23° C.

Reflectance (R(1)=Reflectance at 460 nm (Initial) (%), R(2)=Reflectance at 460 nm (190° C., 24 hrs.) (%) and R(3)=Reflectance at 460 nm (190° C., 72 hrs.) (%)) testing was conducted with Color-Eye 7000A using 2.54 mm color chip. 350(%) was calculated by the following equations:

$$ρ ( λ ) = \frac{{G}_{refl} ( λ )}{{G}_{incid} ( λ )}$$

$${G}_{refl} ( λ ) = {\int }_{380 nm}^{750 nm} Initial luminous flux ( λ ) \times Reflectance ( λ )$$

$${G}_{refl} ( λ ) = {\int }_{380 nm}^{750 nm} Initial luminous flux ( λ ) \times Reflectance ( λ )$$

Initial luminous flux (λ) was obtained from a 3000K Hikari® light source, which was used to measure reflectivity.

Compounding and molding: Compounding and molding procedures are described as follows: All the ingredients except glass fiber were pre-blended, and then extruded using a 37 mm Toshiba® twin-screw extruder. Testing methods, standards and conditions for extruding are listed in Table 3.

TABLE 3

| Parameter | Units | Value |
|---|---|---|
| Die | Mm | 4 |
| Zone 1 Temp | ° C. | 150 |
| Zone 2 Temp | ° C. | 250 |
| Zone 3 Temp | ° C. | 260 |
| Zone 4 Temp | ° C. | 260 |
| Zone 5 Temp | ° C. | 270 |
| Zone 6 Temp | ° C. | 270 |
| Zone 7 Temp | ° C. | 270 |
| Zone 8 Temp | ° C. | 275 |
| Zone 9 Temp | ° C. | 275 |
| Zone 10 Temp | ° C. | 275 |
| Zone 11 Temp | ° C. | 275 |
| Die Temp | ° C. | 280 |
| Screw speed | rpm | 200 |
| Throughput | kg/hr | 30 |

The extruded pellets were molded on a FANUC molding machine in accordance with ASTM standard mold types for mechanical tests. Table 4 shows molding conditions for filled PCT polyester resin.

TABLE 4

| Parameter | Units | Value |
|---|---|---|
| Cnd: Pre-drying time | Hours | 4 |
| Cnd: Pre-drying temp | ° C. | 120 |
| Hopper temp | ° C. | 50 |
| Zone 1 temp | ° C. | 285 |
| Zone 2 temp | ° C. | 290 |
| Zone 3 temp | ° C. | 295 |
| Nozzle temp | ° C. | 290 |
| Mold temp | ° C. | 130 |
| Screw speed | Rpm | 100 |
| Back pressure | kgf/cm² | 50 |

### Examples 1-3

The use of flat glass fiber in a PCT polyester system comprising titanium dioxide was tested for reflectance (at 460 nm) and reflectivity, as well as other physical properties. Rod-shaped 10-μm and 13-μm diameter glass fiber for polyester was used as the control (Comparative Examples 1 (C1) and 2 (C2)). Test compositions are shown in Table 5.

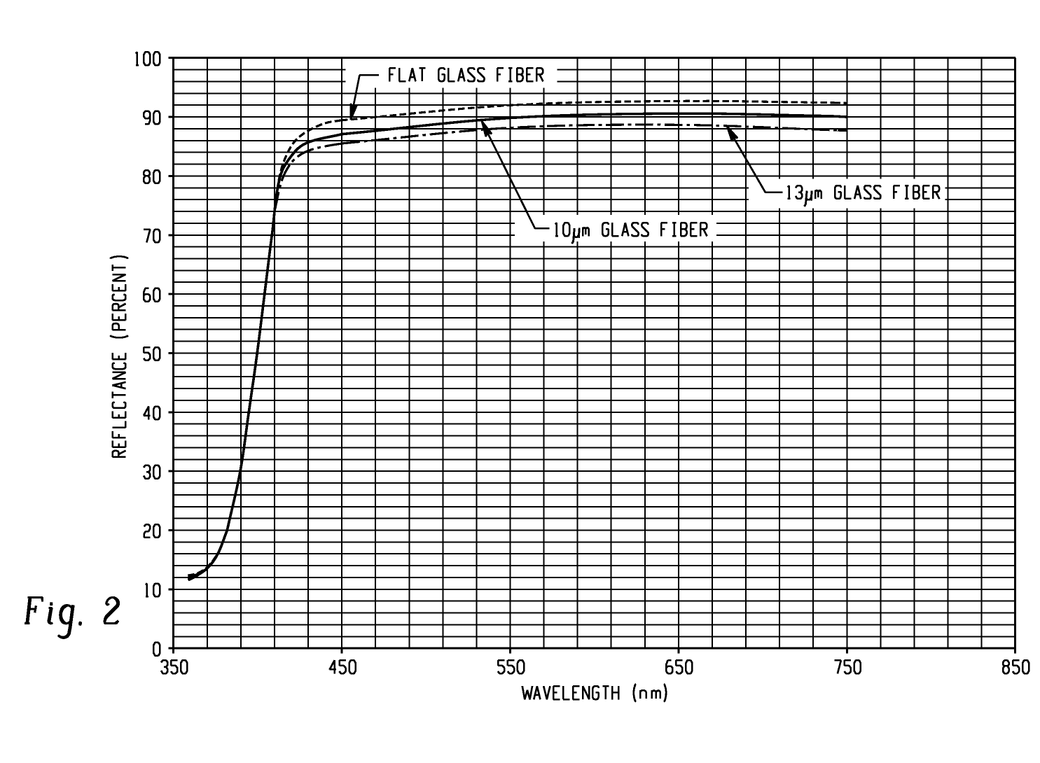

According to the results shown in Table 6 and FIG. 2, the resin composition of E1, having flat glass fiber, obtained a superior reflectance at 460 nm of 91% and a superior reflectivity in the range from 380 nm to 750 nm that was calculated to reach 93%. In contrast, the reflectance for the rod-shaped glass fiber of C1 and C2 was significantly less than 90%. Thus, the resin composition having flat glass fiber exhibited significantly higher performance than those resin compositions using the various rod-shaped glass fibers. Furthermore, flat glass fiber-filled PCT polyester system exhibited slightly higher melt flow rate than the rod-shape glass fiber-filled PCT system. The HDT of the PCT polymer system using flat glass fiber, which reached 240° C. at the loading of 1.82 MPa, was comparable to the use of the rod-shaped glass fiber. Tensile stress and tensile elongation were also comparable.

TABLE 5

| Item | C1 | C2 | E1 | E2 | E3 | E4 | E5 | E6 | E7 | E8 | E9 |
|---|---|---|---|---|---|---|---|---|---|---|---|
| A | 48.64 | 48.64 | 48.64 | 39.64 | 39.64 | 39.64 | 39.64 | 46.54 | 47.84 | 57.9 | 47.9 |
| B1 | | | | 10 | | | | | | | |
| B2 | | | | | 10 | | | | | | |
| B3 | | | | | | 10 | | | | | |
| B4 | | | | | | | 10 | | | | |
| C | 20 | 20 | 20 | 20 | 20 | 20 | 20 | 22.0 | 20.0 | 20.0 | 20.0 |
| D1 | | | 30 | 30 | 30 | 30 | 30 | 30.0 | 30.0 | 20.0 | 30 |
| D2 | 30 | | | | | | | | | | |
| D3 | | 30 | | | | | | | | | |
| E | 1 | 1 | 1 | | | | | 0.50 | 0.50 | 0.50 | 0.50 |
| F | | | | | | | | 0.20 | | | |
| G | | | | | | | | | 0.30 | 0.30 | 0.30 |
| H | | | | | | | | 0.50 | 0.50 | 0.50 | 0.50 |
| I | 0.06 | 0.06 | 0.06 | 0.06 | 0.06 | 0.06 | 0.06 | 0.06 | 0.06 | | |
| J | | | | | | | | | 0.30 | 0.30 | 0.30 |
| K | | | | | | | | | 0.30 | 0.30 | 0.30 |
| L | 0.3 | 0.3 | 0.3 | 0.3 | 0.3 | 0.3 | 0.3 | 0.20 | 0.20 | 0.20 | 0.20 |

TABLE 6

| Test Result (units) | C1 | C2 | E1 | E2 | E3 | E4 | E5 | E6 | E7 | E8 | E9 |
|---|---|---|---|---|---|---|---|---|---|---|---|
| Melt Volume Rate (cm³/10 min) | 15 | 15 | 18 | 19 | 15 | 4 | 3 | — | —* | 35 | 18 |
| Tensile Modulus (MPa) | 9000 | 9300 | 9200 | 10600 | 9300 | 10300 | 10000 | — | — | 7200 | 9200 |
| Tensile Stress (MPa) | 84 | 74 | 87 | 93 | 92 | 88 | 87 | — | — | 62 | 87 |
| Tensile Elongation (%) | 1.1 | 1.1 | 1.3 | 1.2 | 1.5 | 1.2 | 1.2 | — | — | 1.5 | 1.3 |
| Heat Deflection Temperature | 272 | 268 | 275 | 244 | 271 | 275 | 276 | — | — | 275 | 275 |
| (0.45 MPa, ° C.) | | | | | | | | | | | |
| Heat Deflection Temperature | 222 | 213 | 243 | 208 | 100 | 238 | 241 | — | — | 240 | 243 |
| (1.82 MPa, ° C.) | | | | | | | | | | | |
| IZOD Impact Strength (23° C., | 37 | 37 | 50 | — | — | — | — | — | — | 35 | 50 |
| Notched) | | | | | | | | | | | |
| Reflectance at 460 nm (%) | 87 | 86 | 91 | 88 | 89 | 88 | 88 | 91 | 91 | 92 | 91 |
| Reflectance at 460 nm | — | — | — | — | — | — | — | 80 | 86 | — | — |
| (190° C., 24 hrs.) (%) | | | | | | | | | | | |
| Reflectance at 460 nm | — | — | — | — | — | — | — | 65 | 80 | — | — |
| (190° C., 72 hrs.) (%) | | | | | | | | | | | |
| Reflectivity (%) | 90 | 89 | 93 | 92 | 92 | 91 | 90 | — | — | 95 | 93 |

*not available as indicated

The resin compositions in the form of a plate, 1 mm in thickness, were also tested to determine whether the resin composition with flat glass fiber would maintain its reflectance under the process conditions expected for SMT (Surface Mount Technology) during LED packaging. SMT process simulation was conducted at 260° C., for 1 or 5 min, after pre-heat aging at 85° C. and 85% humidity for 168 hrs. The resin compositions were tested for reflectance at the initial stage and after the SMT simulated process to determine whether the flat glass fiber-filled PCT polymer system could maintain reflectance from 360 nm to 750 nm

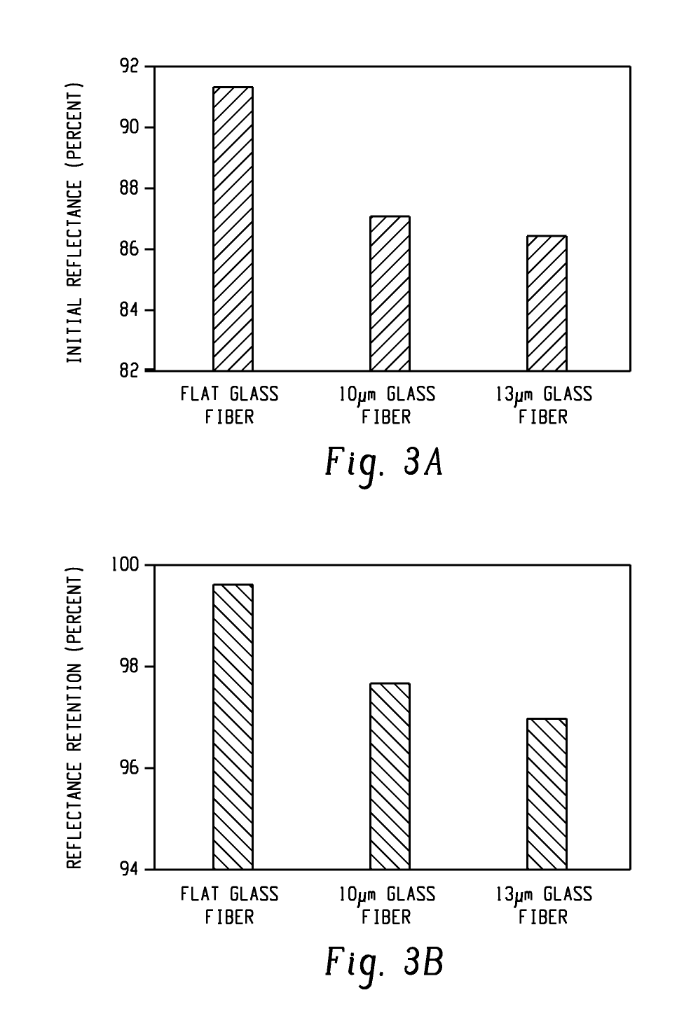

In particular, FIG. 3 shows a comparison of reflectance for resin compositions using flat glass fiber and two rod-shaped glass fibers. Specifically, (A) initial reflectance; and (B) reflectance retention after a simulated SMT process at 260° C. for 5 min after pre-heat aging at 85° C. at 85% humidity for 168 hrs.

Reflectance retention of the PCT polymer system using flat glass fiber reached almost 100%, while that using 10 μm and 13 μm rod-shaped glass fibers dropped to about 98% and 97%, respectively (FIG. 3B). As a result, it was found that flat glass fiber can provide a resin composition that can withstand the SMT process, while providing both high initial reflectance and reflectance retention after the SMT process.

### Examples 2-5

Based on the positive results for using flat glass fiber, various polymer blends were tested. Four other types of materials were introduced into PCT polymer system, including polybutylene terephthalate (PBT), TRITAN copolyester, polyamide 9T (PA9T), and polyphthalamide (PPA). Test compositions and the results are also shown in Tables 5 and 6.

The results for Examples 2-5 showed that various polymer blends comprising flat glass fiber exhibited outstanding reflectance and reflectivity. When comparing to other physical properties, the tensile stress and elongation of the compositions of Examples 2-5 were similar with the previous PCT polymer system of Example 1. The lower MVR of Examples 4 and 5 was attributed to the high melting temperature of PPA and PA9T, which were not completely melting at the test conditions for pure PCT polymer. However, both of these blends retained similar HDT values compared to the use of non-blended PCT polymer. Examples 2 and 3 were found to have lower HDT values as a result of the lower melting temperature of PBT and TRITAN copolyester. They passed the SMT simulation process with good reflectance retention.

### Examples 6-7

Based on the positive results using flat glass fiber, different stabilizer compositions were tested to determine reflectance retention. Test compositions and the results are further shown in Tables 5 and 6. The results of these trials, using different stabilizer packages in the polymer blends comprising flat glass fiber, showed that outstanding initial reflectance and reflectivity was obtained for various stabilizer packages. Reflectance retention was determined by subjecting the compositions (in the form of a plate, 1 mm thickness) to a temperature of 190° C. for 24 hour and 72 hour periods of time. Without prior preheating or humidity, the resin compositions were tested for reflectance at the initial stage and after the heat aging, to determine whether the flat glass fiber-filled PCT polymer system could maintain reflectance at 460 nm. The stabilizer package of Example 6, containing the thioether ester, phosphonite, and quencher (mono zinc phosphate), provided superior reflectance retention, compared to an initial stabilizer package.

Specifically, under the conditions tested, reflectance retention of the PCT polymer system of Example 6 was at least 80 percent, whereas the other stabilizer package obtained reflectance retention of 65 percent after 72 hours. Thus, the stabilizer package used can provide further improvement with respect to reflectance retention.

### Examples 8-9

Based on the positive results for using flat glass fiber, different amounts (loadings) of the flat glass fiber were tested to determine its effect on reflectance and reflectivity. Test compositions and the results are likewise shown in Tables 5 and 6. The initial reflectance at 460 nm was high for both flat glass fiber loadings. Specifically, Examples 8-9 obtained a reflectance at 460 nm of 92% and 91%, respectively. Thus, even at a lower flat glass fiber loading of 20 wt. % significantly higher performance was obtained compared to resin compositions using various rod-shaped glass fibers at 30 wt. % loadings (comparing the results in Table 6). The lower loading of flat glass fiber in the glass fiber-filled PCT polyester system exhibited higher melt flow and slightly higher tensile elongation rate, while the higher loading of flat glass fiber in the glass fiber-filled PCT polyester system of Example 9 exhibited higher tensile modulus, tensile stress, and Izod impact strength. The HDT were comparable. Thus, the loadings of glass fiber in the compositions can be adjusted depending on the particular balance of properties that may be desired for a particular application.

While the invention has been described with reference to a preferred embodiment, it will be understood by those skilled in the art that various changes can be made and equivalents can be substituted for elements thereof without departing from the scope of the invention. In addition, many modifications can be made to adapt a particular situation or material to the teachings of the invention without departing from essential scope thereof. Therefore, it is intended that the invention not be limited to the particular embodiment disclosed as the best mode contemplated for carrying out this invention, but that the invention will include all embodiments falling within the scope of the appended claims.

### REFERENCE NUMBERS IN FIGURES

1 surface-mount LED unit
2 Meal lead frame
3 LED chip
4 Die Pad
5 Conductive wire
6 Transparent sealing resin

What is claimed is:

1. A resin composition for molding a reflector for a light-emitting diode comprising:
about 25 to about 80 wt. % of a heat-resistant aromatic polyester having a melting point of at least 260° C. of which
at least about 80 mole percent of diol repeat units in the polyester, derivable from 1,4-cyclohexanedimethanol, are of formula (I): 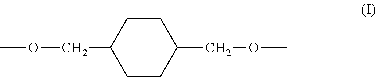
and at least about 80 mole percent of dicarboxylic acid repeat units in the polyester, derivable from terephthalic acid, are of formula (II): 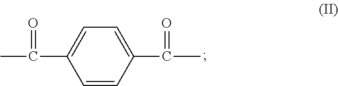
about 5 to 50 wt. % of white titanium dioxide filler; and
about 5 to 50 wt. % of glass fiber having a flat surface.

2. The resin composition of claim 1, wherein the heat-resistant aromatic polyester is selected from the group consisting of poly(1,4-cyclohexanedimethylene terephthalate), poly(1,4-cyclohexylene dimethylene terephthalate-co-isophthalate), poly(1,4-cyclohexylene dimethylene co-ethylene terephthalate), and mixtures thereof.

3. The resin composition of claim 1, wherein the heat-resistant aromatic polyester is poly(1,4-cyclohexanedimethylene terephthalate).

4. The composition of claim 1, wherein the composition comprises, in addition to the heat-resistant aromatic polyester, an organic resin selected from the group consisting of polybutylene terephthalate, polypropylene terephthalate, polyethylene terephthalate, copolyesters comprising 2,2,4,4-tetramethyl-1,3-cyclobutanediol units, nylon 6,6, polyphthalamide, copolymers of the forgoing polymers, and a combination thereof, in an amount of between 1 and 40 wt. %, based on the total weight of the composition, and 2 to 49 wt. % based on the total weight of resin in the composition.

5. The composition of claim 6, wherein the composition comprises, in addition to the heat-resistant aromatic polyester, an organic resin selected from the group consisting of polybutylene terephthalate, polypropylene terephthalate, and combinations thereof.

6. The composition of claim 1, wherein the composition further comprises a white inorganic filler selected from the group consisting of potassium titanate, zirconium oxide, zinc sulfide, zinc oxide, barium sulfate, magnesium oxide, and mixtures thereof.

7. The composition of claim 1, wherein the titanium dioxide has an inorganic surface treatment with alumina and an organic surface treatment with a polysiloxane compound.

8. The composition of claim 1, wherein at least 90 weight percent of white inorganic filler in the composition is titanium dioxide, based on the total white inorganic filler.

9. The composition of claim 8, wherein the composition further comprises a second inorganic filler that is not titanium dioxide.

10. The composition of claim 1, wherein titanium dioxide is present in an amount of 12 to 30 wt. % based on the total composition.

11. The composition of claim 1, wherein the glass fiber has a trapezoidal, square, or rectangular cross-section.

12. The composition of claim 1, wherein the glass fiber has an average aspect ratio of 1:1 to 5:1 wherein aspect ratio refers to the axial cross-section of the glass fiber.

13. The composition of claim 1, wherein the glass fibers, when compounded into the resin the composition, have an average length of 0.1 mm to 10 mm and an equivalent circular diameter, in cross section, of 5 to 25 micrometers.

14. The composition of claim 1, wherein a molded article comprising the composition has a reflectance at 460 nm of 80 to 98 percent.

15. The composition of claim 1, wherein a molded article comprising the composition has a reflectivity in the range from 380 nm to 750 nm of 80 to 98 percent.

16. A resin composition for molding a reflector for a light-emitting semiconductor diode reflector comprising, the resin composition comprising:
about 30 to about 70 wt. % poly(1,4-cyclohexanedimethylene terephthalate);
about 10 to 30 wt. % of titanium dioxide; and
about 10 to 30 wt. % of a glass fibers having a flat surface and an aspect ratio in cross-section, of 1:1 to 4.5:1; and
0.1 and 10 wt. % of one or more additives selected from the group consisting of mold release agents, antioxidants, quenchers, light stabilizers, nucleating agents and combinations thereof.

17. The resin composition of claim 16, wherein the composition comprises a benzotriazole light stabilizer, a quencher, and an antioxidant selected from the group consisting of an organophosphonite, a thioether ester, and combinations thereof.

18. A reflector for a light-emitting semiconductor diode, comprising a molded product of a resin composition of claim 1, shaped for reflecting light from a light-emitting semiconductor element.

19. A light-emitting semiconductor unit comprising a light-emitting semiconductor element, leads connecting electrodes of a light-emitting semiconductor diode element with external electrodes, respectively; and a reflector for a light-emitting semiconductor unit according to claim 18, including a molded product of a resin composition comprising:
about 25 to about 80 wt. % of an heat-resistant aromatic polyester having a melting point temperature of at least 260° C. of which
at least about 80 mole percent of diol repeat units, derivable from 1,4-cyclohexanedimethanol, are of formula (I): 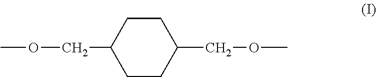
and at least about 80 mole percent of dicarboxylic acid repeat units, derivable from terephthalic acid, are of formula (II): 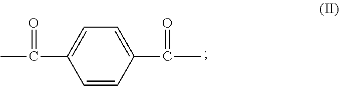
about 5 to 50 wt. % of a titanium dioxide filler; and
about 5 to 50 wt. % of glass fiber having a non-circular or flat surface.

20. A light-emitting semiconductor package comprising a reflector and a solder, wherein the reflector comprises a resin composition comprising:
about 25 to about 80 wt. % of heat-resistant aromatic polyester have a melting point temperature higher than the point of the solder of which
at least about 80 mole percent of diol repeat units, derivable from 1,4-cyclohexanedimethanol, are of formula (I): 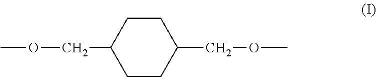
and at least about 80 mole percent of dicarboxylic acid repeat units, derivable from terephthalic acid, are of formula (II): 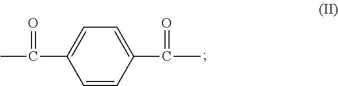
about 5 to 50 wt. % of titanium dioxide filler; and
about 5 to 50 wt. % of glass fiber having a flat surface.

21. A resin composition for molding a reflector for a light-emitting semiconductor unit comprising:
about 25 to about 80 wt. % of an organic resin having a melting point or transition glass temperature of at least 260° C., wherein the organic resin is poly(1,4-cyclohexanedimethylene terephthalate);
about 5 to 50 wt. % of white titanium dioxide filler; and
about 5 to 50 wt. % of glass fiber having a flat surface.

22. A reflector for a light-emitting semiconductor diode, comprising a molded product of a resin composition of claim 21, shaped for reflecting light from a light-emitting semiconductor element.

23. A light-emitting semiconductor unit comprising a light-emitting semiconductor element, leads connecting electrodes of a light-emitting semiconductor element with external electrodes, respectively; and a reflector for a light-emitting semiconductor unit according to claim 22.
